(19) United States
(12) Patent Application Publication
(10) Pub. No.: US 2014/0290157 A1
(43) Pub. Date: Oct. 2, 2014

(54) WINDOW AS SOLAR HVAC PORTAL

(71) Applicant: Roger D. Wilson, Boise, ID (US)

(72) Inventor: Roger D. Wilson, Boise, ID (US)

(21) Appl. No.: 14/006,949

(22) PCT Filed: Mar. 23, 2012
(86) PCT No.: PCT/US2012/030217

§ 371 Date: Dec. 3, 2013

Related U.S. Application Data
(60) Provisional application No. 61/466,878, filed on Mar. 23, 2011.

(51) Int. Cl. H01L 31/048; H02J 7/35; E06B 7/28

(52) U.S. Cl. CPC H01L 31/048; E06B 7/28; H02J 7/35
USPC 52/173.3; 320/101

(57) ABSTRACT

Described are a cooperating solar energy collector panel and an energy converter, at least one of which is adapted to fit within a window opening. Preferably, the solar collector panel and/or energy converter are movable into or within the window opening to allow for the window to still be able to open to let in fresh air, or be free from obstruction to permit entry of light or a view to the outdoors when the solar collector panel and/or energy converter are not in use. In one version, the solar collector panel is adapted to be remote from the window opening, for example, on the top of an awning above the window opening. The bottom of the awning in this case may be adapted to contain an energy converter which may be moved into the window opening to distribute heat into a building.

This application claims benefit of U.S. Provisional Application Ser. No. 61/466,878 filed Mar. 23, 2011, the entire disclosure of which is incorporated herein by this reference.

### BACKGROUND OF THE INVENTION

1. Field of the Invention

This invention relates generally to solar power, and more specifically to using solar power in a way which cooperates with a window in a building so that the window can participate in solar power collection for heating, ventilating and air conditioning (HVAC), and still have the capability to let in fresh air or be unobstructed to let in light or for a view.

2. Related Art

The field of solar power is developing rapidly. Components for collecting energy from sunlight, and converting it to useful power for HVAC in homes, shops, offices and factories are rapidly being improved so they are smaller, lighter, more maneuverable and more economical. Therefore, these solar energy collectors and converters are being used in many new applications.

Still, there is a need for a solar collector/converter which can be easily and effectively installed in order to cooperate with a window opening so that the window can have the capability to still let in fresh air, light or a view while also providing the capability for HVAC. This invention addresses that need.

### SUMMARY OF THE INVENTION

In one embodiment, the present invention includes a solar collector panel which is adapted to fit in the space of an existing window opening. Preferably, the solar collector panel is moveable within the window opening to allow for the window to still be able to open to let in fresh air, or be free from obstruction to permit entry of light or a view to the outdoors.

In one embodiment, the solar collector panel may be stored during periods of non-use in a pocket in the wall around the window opening. The collector panel may be moved sideways, up or down to move into and out of position in the window opening for use. This way, the collector panel is conveniently and securely stowed away, close at hand, for periods of non-use. Also, this way the collector panel may be conveniently and quickly moved into place for use. The movement of the collector panel may be made manually or mechanically by an electric motor, for example, which moves the panel on a track into and out from the window opening.

In another embodiment, the solar collector is a flat panel with the collector facing towards the outside, and a flat panel heater element, and/or a flat panel cooling element facing towards the inside. In this embodiment, the flat panel heater element and the flat panel cooling element may be separate panels installed in separate, parallel tracks for movement into and out from the window opening. A thermostat controller may optionally be operatively connected to the separate panels to control their movement into and out from the position of use, according to the set temperature for the indoors, and the outside weather conditions.

In another embodiment, the solar collector includes a flat panel with the collector facing towards the outside, and a fan, also in the window opening for blowing air into, or exhausting air out from, the room with the window.

In another embodiment, the solar collector includes a flat panel with the collector facing outwards, and another series of panels comprising a fan, and/or a heater element and/or a cooling element for the inside of the room. In this embodiment, one or more of the fan or other elements may be combined together in the side of the panel facing towards the room. Or, the fan or other elements may be in separate panels which move separately, on separate, parallel tracks, for example, into and out from the operable position in the window.

In another embodiment, the solar collector may be remote from the flat panel heater and/or cooling elements and/or fan, which may be powered by the solar energy collected. In another embodiment, the flat panel heater and/or cooling elements and/or fan may also be powered from energy collected from wind, or water or other conventional electricity generating systems and provided to the electricity grid.

In all these above embodiments, the heater and/or cooling elements and/or fan may exist in or for the window opening in addition to the conventional glass and/or screen typically found in window openings today.

The solar collector panel of the present invention may be any currently or later available type solar energy collector. For example, the solar collector may be a tube of heat transfer fluid flowing past a backing coated with a sunlight absorbing material or color. Or, the solar collector may be a tube of heat transfer fluid flowing through the focal point(s) of solar collection mirror(s). Or, the solar collector may be an array of heat pipes filled with a working fluid and operating in a boiling/condensation cycle. Or, the solar collector may be a photovoltaic array. Or the solar collector may be a combination of these above collectors, or other conventional solar energy collectors, or combination thereof. Preferably, the solar collector is in the format of a flat panel.

Also, the energy converter of the present invention may be any currently or later available type collected energy/power converter. For example, the power converter may be a heat exchange system with a heat exchange fluid which, when heated during the day is moved to an insulated storage tank for use later of its higher temperature. This warmed heat exchange fluid is used for heat exchange again, with air via a fan or other blower, for example, to release and distribute the stored heat into a room at night or otherwise when the temperature drops. Or, the power converter may be the direct outputter from a conventional photovoltaic cell. Or, the power converter may be a combination of these above converters, other conventional power converters, and combinations thereof. Preferably, the collected energy/power converter is in the format of a flat panel.

According to one embodiment of the present invention, the solar collector is adapted to fit in the opening of an existing window. Preferably, the solar collector is movable, so that it may be moved into place to be best operable, and moved out of the way to permit the window to allow fresh air in, and the entry of light or a view to the outdoors. Alternatively, the solar collector may be sized so that it takes up only a portion of the window opening space. This way, the solar collector may be operable, and at the same time permit the unobstructed portion of the window to allow in fresh air, light and/or a view.

According to another embodiment of the present invention, the solar collector is remote from the window opening, and adapted to fit, for example, on the top of the awning over the window. The awning solar collector may be adapted to unfold out to increase the surface area for solar collection. The awning top may be adjusted, by rotation to different angles, for example, for maximum solar power collection. The bottom of the awning may contain the collected energy/power converter. For example, the awning may be extended out during the day to collect solar energy. The collected energy may be stored, for example, as hot working fluid, in an insulated storage tank. Then, at night or when the temperature drops, the awning may be moved down until it is vertical and moved so that its bottom fits in the window opening. This way, when the bottom of the awning is adapted to be a heat exchange radiator, for example, stored heat from the hot working fluid in the insulated tank may be exchanged and released into the room with the window.

In another embodiment, the solar collector is adapted to fit on the top of the awning over the window, and the collected energy/power converter may be remote, for example, in the same window opening. Or, the collected energy/power converter may be detachable from the bottom of the awning for being moved separately from the solar collector into the window opening for, for example, heat exchange therein. This way, the solar collector may remain deployed, even while the collected energy/power converter is delivering heat, for example, to the room through the window opening.

For example, according to the invention there may be two windows in the side of a house and two optional solar collectors, one for each window. In Option 1 the solar collector is movable by sliding in a track sideways, for example, into and out from the window opening. The solar collector absorbs solar energy on its outside surface during the day while it is deployed to one side of the window, and the window is therefore unobstructed for letting in air and light, and for providing a view during this time. At night, or when the temperature drops and heat is desired, the solar collector slides over the window opening, and the side of the collector towards the inside of the room is enabled as an energy converter and acts in a radiator fashion, for example, to emit heat into the room. The energy collected during the heat of the day may be transferred from the collector to a working fluid, and saved in an insulated tank, for example. When heat in the room is called for, a pump sends the hot, stored working fluid in heat exchange mode to the inside of the solar collector, which, with assistance from a fan, acts as a furnace to provide forced-air heat to the room.

In Option 2, the solar collector is on the top of an awning for the window, for example, which efficiently captures the sun's rays, and the awning moves down by rotation and/or sliding, and covers the window opening. Then the bottom of the awning may act similarly to the inside of the sliding solar collector described above, to radiate or otherwise distribute desired heat into the room.

Also, according to the invention, there may be a window in the side of a building, and a solar collector in an awning over the window. In an example of this embodiment of the invention, a retro-fit kit attaches to the outside of the building around the bare window opening. The kit has its own window and/or screen which slides up in a channel to cover the window opening when the awning is deployed up in its solar collector operation. Then, when it is desired to move the awning and/or its bottom radiator down to cover the window opening, and deploy the bottom of the awning in its heat distribution operation, the window in the channel slides down to make room for the bottom of the awning in the window opening.

Also, according to the invention there may be a window wherein the solar collector slides back and forth sideways to cover the window when, for example, the heat distribution operation on the back of the solar collector panel is desired.

Also, according to the invention there may be a window wherein the solar collector is in the form of the top of an awning which rotates up to best collect solar energy, and rotates down into the window opening for its bottom side to perform the heat distribution operation.

Also, according to the invention there may be a window wherein the solar collector slides down over the window opening for its back side to provide the heat distribution operation.

Also, according to the invention there may be a window wherein the solar collector and heat radiator are in the form of the top and bottom, respectively, of an awning.

Also, according to the invention there may be a window wherein the solar collector/radiator slides sideways to cover the window opening.

Also, according to the invention there may be a window wherein there are two window units, side-by-side, and wherein the awning solar collector folds out sideways to provide additional solar collector area and capacity.

Also, according to the invention there may be a window wherein the energy converter is remote from the window opening, such as an existing furnace forced-air ducting system, or a hot water heat piping circuit in a building. In this embodiment, the energy for the energy converter is collected by a solar collector within the window opening.

Also, according to the invention there may be a window wherein multiple parallel flat panels are moveable within the window opening.

Also, according to the invention there may be a window wherein a single flat panel is adapted to perform two or more functions selected from glass, cooling, heating, electricity generating, and screen.

### DESCRIPTION OF DRAWINGS

FIG. 1A is a top, side perspective view of a building containing two embodiments of the present invention.

FIG. 1B is an enlarged, schematic, top, side, perspective detail view of the two window units with movable solar collectors in the wall of a building depicted in FIG. 1A.

FIG. 2 is a schematic, top, side perspective view of another embodiment of the invention containing a movable solar collector which cooperates with a window frame containing a movable glass panel.

FIG. 3A is a schematic, side perspective view of another embodiment of the invention containing two window units with movable solar collectors which may fold out to increase working surface area when deployed.

FIG. 3B is a schematic, enlarged detail view of the foldable solar collector depicted in FIG. 3A in a closed position.

FIG. 3C is a schematic, enlarged detail view of the foldable solar collector depicted in FIG. 3A in a fully opened position.

FIG. 4A is a schematic, top, side perspective view of an embodiment of the invention containing several parallel movable panels for a window opening.

FIG. 4B is a schematic, top, cross-sectional view of the embodiment depicted in FIG. 4A.

### DESCRIPTION OF PREFERRED EMBODIMENTS OF THE INVENTION

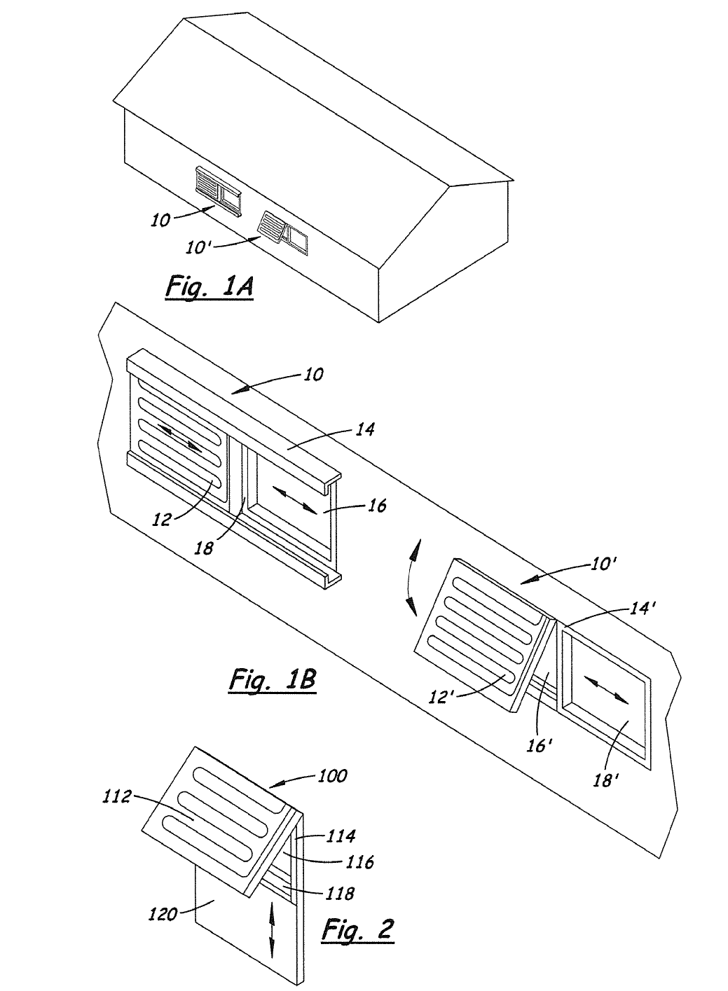

Referring to the FIGS. 1-4B, there are shown several, but not all, embodiments of the invented window as a solar HVAC portal.

FIG. 1A depicts two alternative embodiments, 10 and 10′, of the present invention in the same outside wall of a building.

FIG. 1B depicts an enlarged view of embodiments 10 and 10′ from FIG. 1A. Embodiment 10 has solar collector panel 12 which slides back and forth sideways in frame 14 to cover and uncover window opening 16. Embodiment 10′ has solar collector panel 12′ which rotates outwardly up and down at its top edge at frame 14′ to uncover and cover, respectively, window opening 16′. Windows or screens 18 and 18′ slide back and forth sideways within frames 14 and 14′, respectively, to create window openings 16 and 16′, respectively.

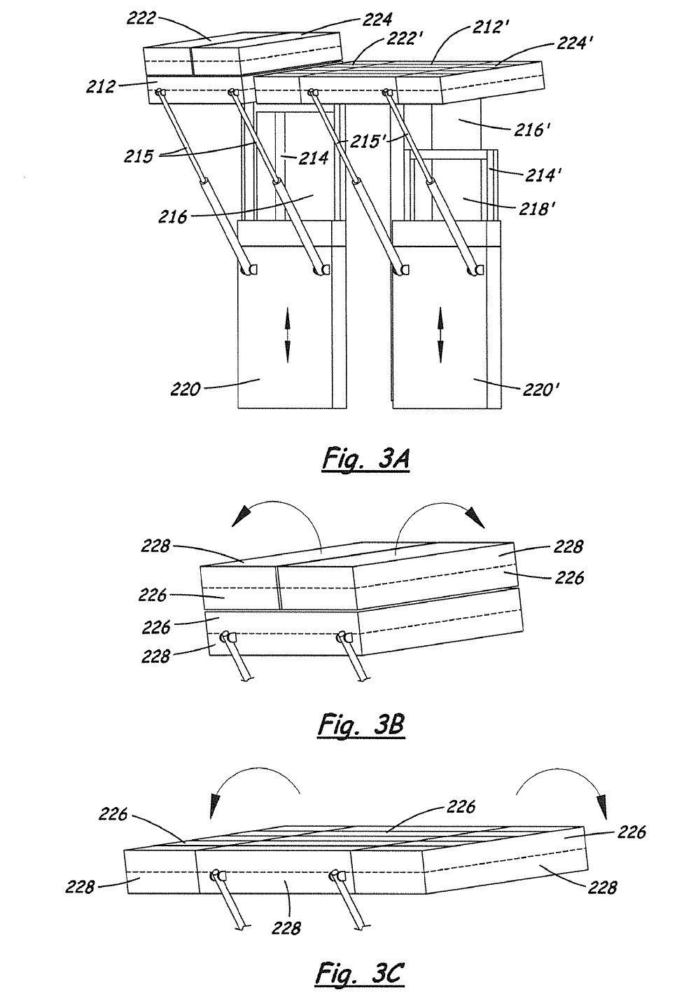

FIG. 2 depicts alternative embodiment 100 of the present invention. Embodiment 100 has solar collector panel 112 which rotates outwardly up and down at its top edge at frame 114 to uncover and cover, respectively, window opening 116. When collector panel 112 is rotated up to make window opening 116, window or screen 118 may be slid up from pocket 120 within frame 114 to cover window opening 116.

FIG. 3A depicts two alternative embodiments 200 and 200′ of the present invention. Embodiment 200 on the left side in the FIG. 3A has solar collector panel 212 which rotates up and outwardly at its bottom inside edge at frame 214 from the extending action of struts 215 to create window opening 216 within frame 214. A window or screen (not shown in this part of the Figure) may be slid up from pocket 220 to cover the window opening 216. Solar collector panel 212 has its main panel part, plus two additional side panel parts, 222 and 224, which rotate out sideways at their top inside edges which are pivotally connected to a top outside edge of panel 212. This way, panel 212 is, in effect, unfolded to increase its working surface area.

Likewise, embodiment 200′ on the right side in the FIG. 3A has solar collector panel 212′ rotated up and outwardly from frame 214′ from the extending action of struts 215′ to create window opening 216′. Here, window or screen 218′ is depicted partly up within frame 214′ to partly cover window opening 216′. Also here, solar collector panel 212′ has two additional panel parts, 222′ and 224′, rotated out sideways to unfold panel 212′.

An enlarged detail view of panel 212, depicting its unfolding/folding capability more fully, is depicted in FIGS. 3B and 3C.

Another enlarged detail view of panel 212 in a fully opened position is depicted in FIG. 3C. There, panel 212 is depicted also as a layered construction. Top panel portion 226 is adapted to have solar collector capability. Top panel portion 226 is effectively exposed to gather energy from the sun. Bottom panel portion 228 is adapted to have energy converter capability. For example, bottom panel portion 228 may be a heat sink with high heat capacity which is warmed substantially from conduction by the solar energy gathered by top panel portion 226. This way, warmed bottom panel portion 228 may radiate heat through window opening 216 when panel 212 is rotated inwardly and down by the retracting action of struts 215. Also, bottom panel portion 228 may be optionally fitted with a fan to also provide convective heating air through window opening 216, the air being warmed by passing over the heat sink.

Alternatively, top panel portion 226 may be operatively connected to a hot water circuit (not shown in FIGS. 3A-C), for example, which receives heat from the top panel portion 226 by conductive and convective heat transfer. In this embodiment, the hot water circuit preferably includes an insulated reservoir so that heat gathered by top panel portion 226 may be collected and stored there during the sunny part of the day when collector panel 212 is deployed outwardly, and then circulated to the bottom panel portion 228 when collector panel 212 is undeployed downwardly into window opening 216 at night. This way, panel 212 is adapted to both collect solar energy on its top panel portion 226 when it's warm outside, and convert and distribute heat from its bottom panel portion 228 into the building through window opening 216 when it's cool outside.

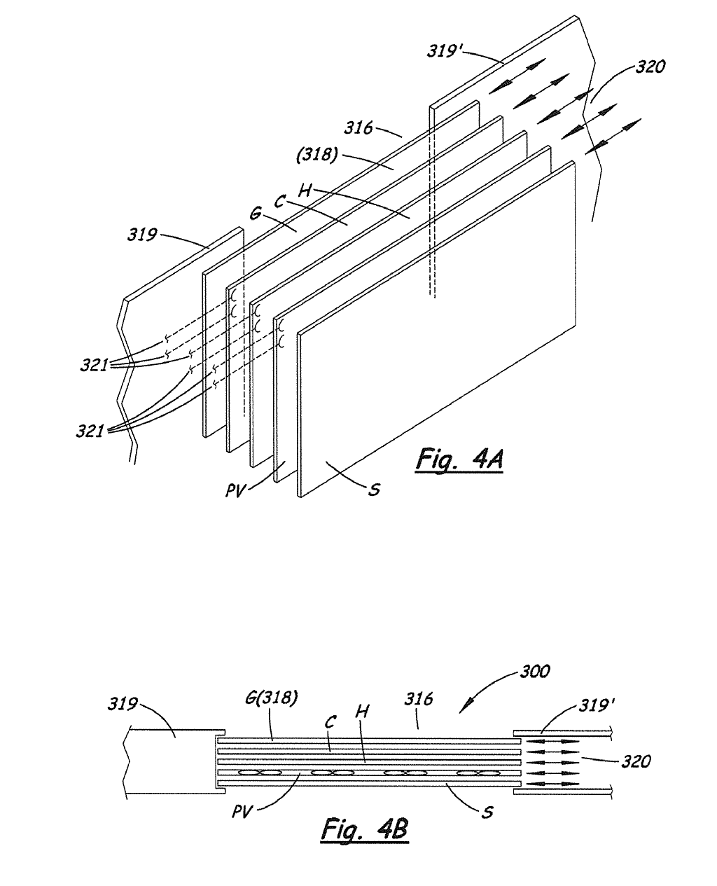

A possibly preferred embodiment 300 of the present invention is depicted schematically in FIGS. 4A and B. FIG. 4A is a top, side perspective view, and FIG. 4B is a top cross-sectional view, of five flat, parallel panels that are moveable within a window opening 316 in a wall 317. The panels typically slide back and forth, generally from left bottom to right top in FIG. 4A, to come into or be removed from their operable position in the window opening 316. Alternatively, one or more of the panels may slide into and out of use, by sliding to the opposite side of the window opening, again into a pocket/recess 320. Or, for more modern-design, utility or industrial rooms, one or more of the panels may slide in a bracket or other guide along a surface of the wall 319 or 319, rather than into a wall pocket/recess 320, to remain visible even when the panel(s) is/are retracted/slid out of the window opening into their inoperable position. Thus, the panels' inoperable position may be to a side portion of part of the window opening (the right side in FIGS. 4A and B, for example), or into a pocket/recess 320 in the wall 319 to the right of the window opening 316 as shown schematically in both FIGS. 4A and B. Alternatively, the panels may be stored above or below the window opening, and rotate or slide down or up, respectively, to fit in the window opening 316 in any conventional manner. Conventional electrical/electronic leads/lines 321 to and from some of the movable panels are shown schematically in dashed lines at the left side of FIG. 4A, for example, for power, monitoring and control of the functions of the panels, energy storage in batteries and/or other storage units, and/or electrical/electronic connection of some panels to each other. Alternatively or in addition, the dashed-line structure (321) may represent other conduits or connections, for example fluid conduits (liquid or gas), between two or more of the panels, and/or between one or more of the panels and conventional equipment, as will be understood by those of skill in the art from this description.

On the outside, for example, is preferably a conventional screen panel (S) to prevent birds and bugs, etc., from entering the window opening. Then, next to the inside is preferably a combination panel of a photovoltaic (PV) array with exposure of the photocells to the outside, and a fan or set of fans on the inside surface. This way, the fan(s) may draw in air to cool the PV, as well as to move the warmed air to the inside of the building from the heater element H, or cool air from the cooling element C, depending upon which function has been selected to be operable. The heater element flat panel (H) is shown towards the inside of the building relative to the photocell/fan panel, as is the cooling element (C). These H and C elements may be combined into one panel. Also, these H and C elements, if separate panels, may be in any relative order, with the H element being outside relative to the C element, or vice versa.

Then, shown on the inside of the panel collection is a conventional glass window G (318), which may also be on the outside of the collection or just inside the screen. The glass and/or other layers may be adapted to allow full or partial opening for better vision and/or air flow through the window opening 316.

Many embodiments of the invention may be broadly described as a solar energy collector and energy converter combination comprising: a solar energy collector operatively connected to an energy converter for a building, with at least one of said collector and said converter being adapted to be movable within a window opening of said building, said solar energy collector providing energy for said converter. The operative connection may be direct and/or contemporaneous, such as the collector operating at the same time the converter is working and with the collector providing energy directly to the converter, for example. Or, for example, the operative connection may be indirect, such as the collector charging batteries or other energy storage units, wherein the batteries or other storage units power the energy converter. Both the solar energy collector and the energy converter may be adapted to be moveable, separately or together, within said window opening.

The solar energy collector and the energy converter may be adapted to slide generally horizontally from an energy-collecting position substantially or entirely outside of the window opening, wherein the energy collector is exposed to sunlight, to an energy-converting position within/covering the window opening wherein the energy converter emits (heats) or withdraws (cools) energy through the window opening into or out of the building, respectively. Alternatively, the solar energy collector and the energy converter may slide generally vertically, or pivot or swing, from an energy-collecting position substantially or entirely outside of the window opening wherein the energy collector is exposed to sunlight, to an energy-converting position within/covering the window opening wherein the energy converter emits/withdraws energy through the window opening into the building. While vertical sliding of solar energy collector and the energy converter is not specifically portrayed in the Figures, this will be understood by those of skill in the art after reading and viewing this document. At least one of a window glass or screen covering the window opening when the collector and converter are in the energy-collecting position may be slidable, pivotal, swingable, or otherwise moveable away from the window opening for allowing the collector and converter to slide, pivot, or swing into/over the window opening to be in said energy-converting position.

In certain embodiments, the collector and converter in the energy-collecting position are to one side of, above, or below, the window opening, parallel to a portion of an exterior wall of the building in which the window opening is provided, and the collector and converter in the energy-converting position are within/covering the window opening and generally parallel to said exterior wall. In certain embodiments, the collector and converter in the energy-collecting position are pivoted upward about 45 degrees or more (for example, 40 degrees up to about 100 degrees, and more preferably 40-90 degrees) from an exterior wall of the building in which the window opening is provided, for increased solar energy collection, and the collector and converter in the energy-converting position are pivoted downward to be generally parallel to said exterior wall and within/covering the window opening.

The collector and converter may be are panels connected together into, or otherwise provided in, a single body (see FIGS. 1A, 1B, 2, 3A-C, for example). The “single body” may be a vertically-slidable body, a horizontally-slidable body, or a pivotal body, for example. Alternatively, the collector and converter may be separate except for any needed operative connection such as electrical/electronic connection or fluid-flow connection, for example. The collector and converter (and/or other panels/bodies such as glass, screen, or fan structure) may each be moveable from within the window opening into a recess/pocket in a wall of the building adjacent to the window, so that the collector is movable into the window opening to be in an energy-collecting position wherein it is exposed to daylight, and the converter is moveable to an energy-converting position within the window opening wherein the energy converter emits/withdraws energy through the window opening into/out of the building. Thus, at least one of a window screen and a window glass, and the collector, converter, and said at least one of a window screen and window glass each may be slidable from the window opening into the recess/pocket. For example, the collector, converter, and said at least one of a window screen and window glass may be independently slidable from the window opening into the recess/pocket. For example, two or more of said collector, converter, and said at least one of a window screen and window glass may be in the window opening at the same time. For example, the collector and converter may be in the window opening at the same time. For example, the collector and converter may be in the recess/pocket and said at least one of a window screen and window glass may be in the window opening. Operative connection between the collector and the converter may comprises storage of energy from the collector in batteries, wherein the batteries may be inside the wall or otherwise adjacent to the window opening, or distant from the window opening.

One may note that the energy converter may be described in certain embodiments as emitting or withdrawing heat energy to/from the building, or at least a room of the building. This may be in the form of emitting heat into the building, in many embodiments, through the window opening, for example. This may be in the form of withdrawing heat from the building, in many embodiments, through the window opening, for example. Thus, in certain embodiments, the energy converter comprises a cooling element, and, in certain embodiments, the energy converted comprises a heating element. In certain embodiments, the energy collector comprises a photovoltaic panel, and may optionally be operatively connected to batteries and battery-charging and -discharging control systems.

Although this invention has been described above with reference to particular means, materials and embodiments, it is to be understood that the invention is not limited to these disclosed particulars, but extends instead to all equivalents within the broad scope of the following Claims.

I claim:

1. A solar energy collector and energy converter combination comprising:
a solar energy collector operatively connected to an energy converter for a building, with at least one of said collector and said converter being adapted to be movable within a window opening of said building, said solar energy collector providing energy for said converter.

2. The combination of claim 1 wherein both the solar energy collector and the energy converter are adapted to be moveable within said window opening by sliding or pivoting from an energy-collecting position substantially or entirely away from the window opening to an energy-converting-position partially or entirely within or covering the windowing.

3. The combination of claim 1, wherein both the solar energy collector and the energy converter are adapted to be moveable together within said window opening by sliding or pivoting from an energy-collecting position substantially or entirely away from the window opening to an energy-converting-position partially or entirely within or covering the windowing.

4. The combination of claim 1, wherein the solar energy collector and the energy converter slide generally horizontally from an energy-collecting position substantially or entirely outside of the window opening wherein the energy collector is exposed to sunlight, to an energy-converting position within/covering the window opening wherein the energy converter emits/withdraws heat through the window opening into/out of the building.

5. The combination of claim 4, wherein at least one of a window glass or screen covers the window opening when the collector and converter are in the energy-collecting position and wherein said at least one of a window glass or screen is slidable away from the window opening for allowing the collector and converter to slide into/over the window opening to be in said energy-converting position.

6. The combination of claim 1, wherein the solar energy collector and the energy converter slide generally vertically from an energy-collecting position substantially or entirely outside of the window opening wherein the energy collector is exposed to sunlight, to an energy-converting position within/covering the window opening wherein the energy converter emits/withdraws heat through the window opening into/out of the building.

7. The combination of claim 6, wherein at least one of a window glass or screen covers the window opening when the collector and converter are in the energy-collecting position and wherein said at least one of a window glass or screen is slidable away from the window opening for allowing the collector and converter to slide into/over the window opening to be in said energy-converting position.

8. The combination of claim 1, wherein the solar energy collector and the energy converter pivot From an energy-collecting position substantially or entirely outside the window opening wherein the energy collector is exposed to sunlight, to an energy-converting position within/covering the window opening wherein the energy converter emits/withdraws heat through the window opening into/out of the building.

9. The combination of claim 8, wherein at least one of a window glass or screen covers the window opening when the collector and converter are in the energy-collecting position and wherein said at least one of a window glass or screen is slidable away from the window opening for allowing the collector and converter to pivot into/over the window opening to be in said energy-converting position.

10. The combination of claim 8, wherein at least one of a window glass or screen covers the window opening when the collector and converter are in the energy-collecting position and wherein said at least one of a window glass or screen is pivotal away from the window opening for allowing the collector and converter to pivot into/over the window opening in said energy-converting position.

11. The combination of claim 8, wherein the collector and converter in the energy-collecting position are to one side of the window opening, parallel to a portion of an exterior wall of the building in which the window opening is provided, and wherein the collector and converter in the energy-converting position are within/covering the window opening and generally parallel to said exterior wall.

12. The combination of claim 8, wherein the collector and converter in the energy-collecting position are pivoted upward about 45 degrees or more from an exterior wall of the building in which the window opening is provided, for increased solar energy collection, and wherein the collector and converter in the energy-converting position are pivoted downward to be generally parallel to said exterior wall and within/covering the window opening.

13. (canceled)

14. (canceled)

15. (canceled)

16. The combination of claim 1, wherein the energy collector comprises a photovoltaic panel and wherein the energy converter comprises an element selected from the group consisting of: a cooling element for cooling at least a room of the building and a heating element for heating at least a room of the building.

17. (canceled)

18. (canceled)

19. (canceled)

20. The combination of claim 1, wherein said collector and said converter each are moveable from within the window opening into a recess/pocket in a wall of the building adjacent to the window, so that the collector is movable into the window opening to be in an energy-collecting position wherein the energy collector is exposed to sunlight, and the converter is moveable to an energy-converting position within the window opening wherein the energy converter supplies energy to the building through the window opening.

21. The combination of claim 20, wherein the energy collector comprises a photovoltaic panel and wherein the energy converter comprises a element selected from the group consisting of a cooling element and a heating element.

22. (canceled)

23. (canceled)

24. The combination of claim 20 further comprising at least one of a window screen and a window glass, and the collector, converter, and said at least one of a window screen and window glass each are slidable from the window opening into the recess/pocket.

25. The combination of claim 24, wherein said collector, converter, and said at least one of a window screen and window glass arc independently slidable from the window opening into the recess/pocket.

26. (canceled)

27. The combination of claim 24, wherein said collector and converter are in the window opening at the same time.

28. The combination of claim 24, wherein the collector and converter are in the recess/pocket and said at least one of a window screen and window glass are in the window opening.

29. The combination of claim 1, wherein the operative connection between the collector and the converter comprises storage of energy from the collector in batteries.

30. The combination of claim 20, wherein the operative connection between the collector and the converter comprises storage of energy from the collector in batteries.
